(19) United States
(12) Patent Application Publication
(10) Pub. No.: US 2026/0009131 A1
(43) Pub. Date: Jan. 8, 2026

(54) SEMICONDUCTOR PROCESSING TOOL WITH ADJUSTABLE GAS FLOW DISTRIBUTION

(71) Applicant: Taiwan Semiconductor Manufacturing Company, LTD., Hsinchu (TW)

(72) Inventor: Kun-Han Lu, Hsinchu (TW)

(21) Appl. No.: 18/761,635

(22) Filed: Jul. 2, 2024

(51) Int. Cl. C23C 16/455; C23C 16/52; H01J 37/32

(52) U.S. Cl. CPC C23C 16/45565; C23C 16/45587; C23C 16/52; H01J 37/32082; H01J 37/32449; H01J 2237/3321; H01J 2237/3323; H01J 2237/334

(57) ABSTRACT

A gas distribution plate for a semiconductor processing apparatus includes a mounting plate having through-holes, and iris diaphragms or slotted apertures mounted over or in respective through-holes of the mounting plate. Each iris diaphragm or slotted aperture includes a motorized actuator operable to adjust the opening of the iris diaphragm or slotted aperture. In some embodiments, the gas distribution plate includes iris diaphragms, each including a hinge ring, a rotating ring, and iris leaves each having a first end coupled with the hinge ring and a second end opposite the first end slidably coupled with the rotating ring. If motorized, the motorized actuator may include a motor and a worm drive driven by the motor, with the worm drive operatively coupled with gear teeth disposed on the rotating ring.

### BACKGROUND

The following relates to semiconductor processing apparatuses such as (by way of nonlimiting illustrative example) dry etching tools, plasma etching tools, chemical vapor deposition (CVD) tools, plasma-enhanced chemical vapor deposition (PECVD) tools, and the like; and to gas distribution plates or showerheads for the process chamber of such semiconductor processing apparatuses; and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a perspective view of a semiconductor processing apparatus including a process chamber containing a gas distribution plate or shower head with holes comprising openings of iris diaphragms.

FIG. 2 diagrammatically illustrates an isolation top view of a gas distribution plate or shower head for a semiconductor processing apparatus with holes comprising openings of iris diaphragms.

FIG. 3 diagrammatically illustrates a side sectional view of a gas distribution plate or shower head for a semiconductor processing apparatus with holes comprising openings of iris diaphragms.

FIGS. 4A and 4B diagrammatically illustrate side sectional views of a portion of the semiconductor etching apparatus of FIG. 1 with the iris diaphragms set: to provide a higher gas flow at a periphery of a semiconductor wafer undergoing etching (FIG. 4A); or to provide a higher gas flow at a center of a semiconductor wafer undergoing etching (FIG. 4B).

FIG. 5 diagrammatically illustrates a top view of a mounting plate of a gas distribution plate or shower head for a semiconductor processing apparatus with through-holes for iris diaphragms, and some illustrative iris diaphragms for mounting over or in respective through-holes of the mounting plate.

FIG. 6 diagrammatically illustrates a side sectional view of a portion of a semiconductor processing apparatus including a gas distribution plate or shower head with holes comprising openings of iris diaphragms.

FIG. 7 diagrammatically illustrates a top view of a gas distribution plate or shower head for a semiconductor processing apparatus with holes comprising openings of iris diaphragms, and an illustrative iris diaphragm and components thereof according to one nonlimiting illustrative embodiment.

FIG. 8 diagrammatically illustrates a top view of a gas distribution plate or shower head for a semiconductor processing apparatus with holes comprising openings of iris diaphragms, and an illustrative iris diaphragm and components thereof according to one nonlimiting illustrative embodiment.

FIGS. 9A and 9B shows top views of a slotted aperture for providing a gas distribution plate with adjustable openings, where FIGS. 9A and 9B show the slotted aperture with two nonlimiting illustrative opening settings.

FIG. 10 diagrammatically illustrates a top view of a gas distribution plate or shower head for a semiconductor processing apparatus with holes comprising openings of iris diaphragms, and an illustrative four central iris diaphragms configured for independent manual adjustment of the respective iris diaphragms according to one nonlimiting illustrative embodiment.

FIG. 11 diagrammatically illustrates a top view of a gas distribution plate or shower head for a semiconductor processing apparatus with holes comprising openings of iris diaphragms, and an illustrative four central iris diaphragms configured for independent automated adjustment of the respective iris diaphragms according to one nonlimiting illustrative embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A wide range of semiconductor processing apparatuses (also referred to herein as semiconductor processing tools) employ a process chamber into which gas is flowed, with the objective of depositing material contained in the gas onto a semiconductor wafer (deposition processes), or removing material from the semiconductor wafer (etching processes). Some such semiconductor processing apparatuses may utilize high voltage radio frequency (RF) power applied by electrodes to ionize atoms or molecules of the gas, with the resulting ionized atoms or molecules forming a plasma that deposits onto or etches the semiconductor wafer. Some nonlimiting illustrative examples of such semiconductor processing apparatuses include: dry etching tools; plasma etching tools; chemical vapor deposition (CVD) tools; plasma-enhanced chemical vapor deposition (PECVD) tools; and the like. In some cases, a single semiconductor processing apparatus may be able to perform multiple processes (e.g., different types or modalities of deposition and/or etching) depending on the choice of gas (which may be a mixture of two or more gases, e.g., a process gas and a carrier gas, or two process gases, as nonlimiting illustrative examples), whether plasma generation is employed, and/or by adjusting other process parameters.

In such a semiconductor processing apparatus, a gas distribution plate or showerhead (hereinafter referred to as a “gas distribution plate”) is arranged in the process chamber to distribute the gas flowing onto the semiconductor wafer. The gas distribution plate includes holes formed therein through which the gas flows when entering the process chamber. The flow pattern of the gas through the semiconductor process chamber and onto the semiconductor wafer is controlled by the holes size or sizes, and the distribution of the holes over the gas distribution plate. To this end, the hole size or sizes, and the distribution of the holes over the gas distribution plate, is optimized for a particular make and model of process chamber (e.g., as described by the geometry of its interior chamber walls), usually with the goal of maximizing uniformity of the gas over the lateral surface area of the semiconductor wafer undergoing processing. Such optimization may be done via gas flow simulations and/or by empirical testing, for example by depositing test layers and measuring the deposited layer thickness across the wafer using ellipsometry or another suitable thickness characterization technique.

However, uniformity of the flow pattern of the gas on the semiconductor wafer in a particular semiconductor wafer process may also be affected by other factors and/or process parameters or variables, such as by way of nonlimiting illustrative example: the chamber pressure, the gas flow rate measured in standard cubic centimeters per minute (sccm) or another suitable flow rate unit, the temperature of the semiconductor wafer (which is often heated during the processing using a heater of an electrostatic chuck or other wafer mount), the high voltage RF power settings for producing the plasma (if used), the composition of the gas flowed into and through the process chamber during the semiconductor wafer processing, gas-phase chemical reactions between concurrently applied process gases, contaminant buildup on the interior walls of the chamber and/or on the gas distribution plate, the size of the semiconductor wafer undergoing processing, characteristics of the surface of the semiconductor wafer (e.g., whether it is coated with a patterned photoresist layer, which may impact the gas flow boundary layer at the wafer surface), various combinations thereof, and/or so forth.

Consequently, the gas distribution plate optimized for the process chamber may exhibit suboptimal gas flow uniformity for different types of semiconductor wafer processing. Furthermore, run-to-run the gas flow uniformity may degrade over time even for the same type of semiconductor wafer processing, as contaminants deposited on the gas distribution plate and/or interior walls of the process chamber accumulate run. The deposited film thickness map produced by CVD, PECVD, or other types of deposition processes has a strong relationship with process gas flow distribution; and similarly the etch depth map produced by dry etching, PECVD, or other types of etching processes has a strong relationship with process gas flow distribution. Suboptimal gas flow uniformity can thus lead to process variability across the semiconductor wafer, and the integrated circuit (IC) dies or devices of an array of IC dies or devices being fabricated on a semiconductor wafer will correspondingly have variability that can adversely impact IC or device performance and/or yield.

In embodiments disclosed herein, a gas distribution plate is employed which advantageously includes iris diaphragms. The holes of the gas distribution plate are the openings of the iris diaphragms. The iris diaphragms are adjustable to adjust the sizes of the openings of the iris diaphragms, thus enabling configuring the distribution of the process gas by adjusting sizes of the holes of the gas distribution plate. In a corresponding method, a gas is flowed into a process chamber containing a semiconductor wafer. The gas is distributed onto the surface of the semiconductor wafer by flowing the gas through holes of a gas distribution plate. The distribution of the gas is configured by adjusting sizes of the holes of the gas distribution plate. Thus, embodiments of the gas distribution plate disclosed herein advantageously enable the openings of the gas distribution plate to be configured to optimize the distribution of the gas at the semiconductor wafer for a particular semiconductor wafer processing operation. The iris diaphragms can be set to differently sized openings for different semiconductor wafer processing runs, to optimize the semiconductor processing apparatus for specific runs.

Furthermore, the iris diaphragms can advantageously be adjusted over time to accommodate (e.g., correct for) changes in gas distribution over time due to contaminant buildup on the process chamber walls and/or on the gas distribution plate itself.

In some embodiments, disclosed herein, the iris diaphragms may be individually motorized to enable automatic adjustment of the openings of the individual iris diaphragms. This advantageously enables the gas distribution plate hole settings to be automatically adjusted using the motors prior to a particular processing run, enabling rapid optimization of the gas distribution plate for different process runs. A further advantage of motorized iris diaphragms is that this enables the holes of the gas distribution plate to be changed during a process run, enabling different configurations of the gas distribution at the semiconductor wafer when different gases are flowing, for example. As a specific nonlimiting illustrative example, if the process run is an etching process run that performs a first etch using a first etching gas followed by a second etch using a second etching gas, the motorized iris diaphragms can be initially automatically adjusted to optimize the gas distribution plate for the first etch, then can be automatically adjusted between the first and second etches to optimize the gas distribution plate for the second etch. As previously noted, the optimal holes for the gas distribution plate could be different for the first and second etches for numerous reasons, such as (by way of nonlimiting illustrative example) a change in chamber pressure between the first and second etches, a difference in gas flow rate between the first and second etches, a change in the temperature of the semiconductor wafer between the first and second etches (e.g., implemented using the wafer heater of the wafer mount 20), a difference in RF power settings between the first and second etches (or, use of RF power in only one of these etches), differences in gas-phase chemical reactions between the first and second etches, various combinations thereof, and/or so forth.

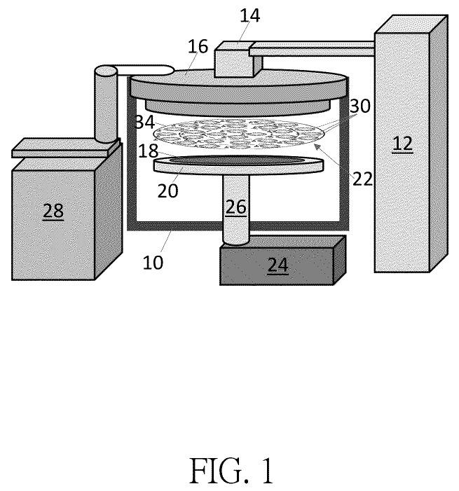

With reference to FIG. 1, a perspective view is diagrammatically shown of a semiconductor processing apparatus, which includes a process chamber 10. A gas source, such as an illustrative gas panel 12, supplies gas to the process chamber 10 via a gas inlet or gas mixer 14. A lid 16 of the process chamber 10 can be opened (when the semiconductor processing apparatus is not in use) to provide access to the interior of the process chamber 10, for example to mount or place a semiconductor wafer 18 onto a wafer mount 20. In the nonlimiting illustrative example, the gas mixture 14 is connected with the lid 16 of the process chamber 10 by a suitable gas coupling, and the lid 16 includes a gas distribution plate 22 is mounted on the lid 16 (in the illustrative orientation, below the lid 16). The gas distribution plate 22 is thus disposed in the process chamber 10 when the lid 16 is closed. In diagrammatic FIG. 1, the gas distribution plate 22 is shown removed from the lid 16 for illustrative purposes.

The wafer mount 20 includes an electrostatic chuck, a vacuum chuck, clips, or another mechanism for holding the semiconductor wafer 18 on the wafer mount 20 during processing of the semiconductor wafer 18 using the semiconductor processing tool of FIG. 1. The wafer mount 20 may also include other features such as a heater for heating the semiconductor wafer 18 to a desired temperature for the semiconductor wafer processing (e.g., material deposition or etching). A bottom module 24 optionally includes electrical feedthroughs to deliver operational power to components of the wafer mount 20, such as the electrostatic chuck, the wafer heater, and/or so forth. The bottom module 24 also optionally includes a motor for rotating the wafer mount 20 and the mounted wafer 18 via a shaft 26 at a rotational speed during the wafer processing. Such rotation can improve uniformity of the deposition, etching, or other wafer processing. The rotating shaft 24 connecting the wafer mount 20 to the bottom module 24 is implemented as a rotary vacuum-tight feedthrough to maintain a gas-tight seal of the process chamber 10 which is typically, although not necessarily, maintained at a sub-atmospheric pressure during the wafer processing. In some embodiments, a radio frequency (RF) generator 28 applies high voltage RF power via electrodes of the process chamber 10 to ionize atoms or molecules of the gas delivered into the process chamber 10 from the gas panel 12 via the gas inlet or gas mixer 14 and gas distribution plate 22, with the resulting ionized atoms or molecules forming a plasma inside the process chamber 10. In the illustrative example of FIG. 1, the electrodes (not shown) include one electrode integrated into the lid 16 and the other electrode integrated into the wafer mount 20.

During a process run, the gas panel 12 supplies one or more constituent gases which (in the case of two or more constituent gases) are mixed by the gas inlet 14 (which in such embodiments is a gas mixer 14) to form the gas as a mixture of the two or more constituent gases. The constituent gas or gases include at least one process gas that is operative to deposit material onto the semiconductor wafer 18 (for a deposition run), or which is operative to etch material of the semiconductor wafer 18 (for an etching run). The constituent gas or gases in the case of a mixture of two or more constituent gases may also include a carrier gas, such as nitrogen, forming gas, or the like, which serves to assist in transport of the constituent process gas or gases to the semiconductor wafer 18.

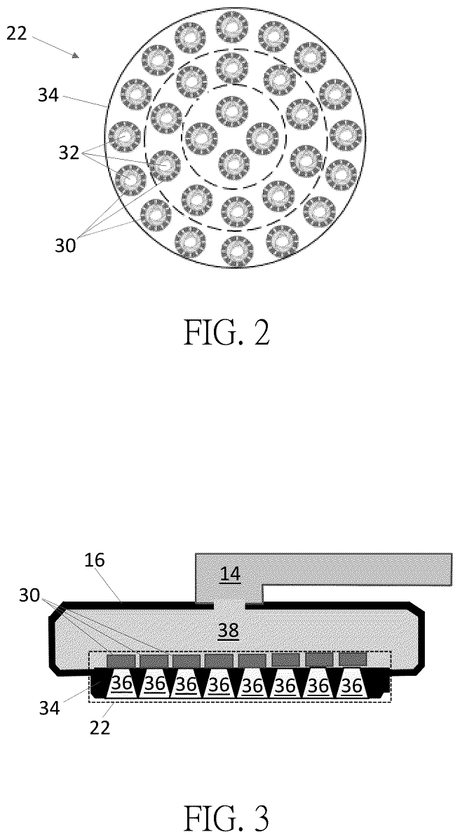

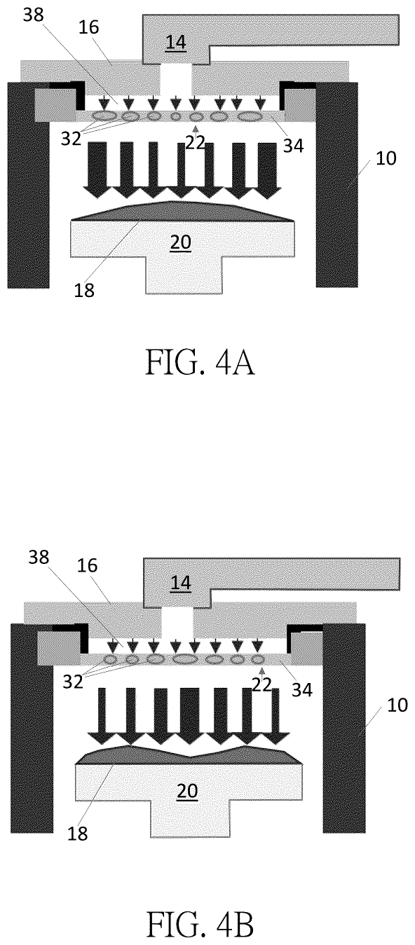

With continuing reference to FIG. 1 and with further reference to FIGS. 2 and 3, the gas distribution plate 22 is further described. FIG. 2 diagrammatically shows an isolation top view of the gas distribution plate (or shower head) 22 with iris diaphragms 30. The holes of the gas distribution plate 22 comprise openings 32 of the iris diaphragms 30, which are disposed on a mounting plate 34. Each opening 32 can be independently adjusted by operation of the corresponding iris diaphragm 30, thus enabling the holes of the gas distribution plage 22 to be independently adjustable. FIG. 3 diagrammatically shows a side sectional view of the gas distribution plate (or shower head) 22 disposed in the lid 16 of the process chamber 10 (see FIG. 1). As seen in FIG. 3, the mounting plate 34 has through-holes 36 aligned with the respective iris diaphragms 30. The size (e.g., diameter) of each through-hole 36 is equal to or larger than the maximum size of the opening 32 of the iris diaphragm 30 that is aligned with that through-hole 36.

As seen in the side sectional view of FIG. 3, the gas distribution plate 22 is mounted in the lid 16 of the process chamber 10 (see FIG. 1) in such a way that a gas plenum 38 is formed between the lid 16 and the gas distribution plate 22. The gas inlet or gas mixer 14 is connected to feed the gas into the plenum 38, and the gas then passes through the openings (not shown in FIG. 3) of the iris diaphragms 30 into the interior of the process chamber 10 and onto the semiconductor wafer 10. Thus, the gas distribution plate 22 operates to distribute the gas from the plenum 38 into the interior of the process chamber 10. By adjusting the openings 32 of the iris diaphragms 30, the gas distribution in the process chamber 10 can be adjusted. In FIG. 3, the through-holes 36 of the mounting plate 34 are frustoconical in shape with smallest diameter proximate to the iris diaphragms 30 and largest diameter distal from the iris diaphragms 30. This approach can advantageously reduce or eliminate the impact of any stagnant gas flow layer proximate to the sidewalls of the through-holes 36. However, the shape of the through-holes 36 can be variously designed.

In the illustrative example of FIG. 2, the openings 32 of the iris diaphragms 30 are illustrated in FIG. 2 as being of about the same size for all the iris diaphragms 30. As just noted, these openings 32 can be individually adjusted by operation of the corresponding iris diaphragms 30.

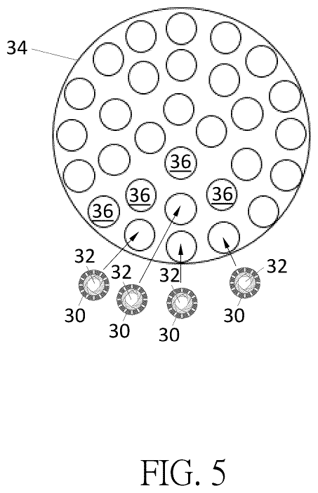

With reference now to FIGS. 4A and 4B, an example of such adjustment is diagrammatically shown. FIGS. 4A and 4B diagrammatically illustrate side sectional views of a portion of the semiconductor etching apparatus of FIG. 1, including a portion of the process chamber 10 with its lid 16 and the gas inlet or gas mixer 14 coupled therewith, the wafer mount 20 with the semiconductor wafer 18 disposed therein, and the gas distribution plate 22 with its mounting plate 34 and the openings 32 of the iris diaphragms diagrammatically depicted. FIGS. 4A and 4B diagrammatically depict an etching process, in which material of the upper surface of the semiconductor wafer 18 is being etched. FIG. 4A illustrates an example in which the iris diaphragms 30 are set with larger openings at the periphery of the gas distribution plate 22 and smaller openings near the center of the gas distribution plate 22. This results in a higher flow of the etchant gas at the periphery of the semiconductor wafer 18, producing more etching at the periphery of the semiconductor wafer 18 as seen in FIG. 4A. FIG. 4B illustrates an example in which the iris diaphragms 30 are set with smaller openings at the periphery of the gas distribution plate 22 and larger openings near the center of the gas distribution plate 22. This results in a higher flow of the etchant gas at the center of the semiconductor wafer 18, producing more etching at the center of the semiconductor wafer 18 as seen in FIG. 4B. In similar fashion, for a deposition process areas with higher gas flow usually produce faster deposition and hence a thicker deposited layer, compared with areas with lower gas flow where the deposited layer is thinner.

FIGS. 4A and 4B depict examples of configuration of the openings 32 of the gas distribution plate 22 being set to produce laterally nonuniform etching. In many applications, the goal is to achieve uniform etching (or uniform-thickness deposition) laterally across the semiconductor wafer 18. However, undesired lateral nonuniformity can be produced as a result of various factors such as (by way of nonlimiting illustrative example) effects of the interior sidewalls of the process chamber 10 impacting the gas flow distribution, temperature variation laterally across the semiconductor wafer 18, nonuniform density of the gas in the plenum 38, variation in the RF field (if plasma assisted etching or deposition is being performed), various combinations thereof, and/or so forth. In such cases, the configuration of the openings 32 of the iris diaphragms 30 can advantageously be adjusted to compensate for such sources of nonuniformity and provide more laterally uniform etching or deposition.

For advantageous ease of manufacturability and interchangeability of parts, in some embodiments the through-holes 36 all have the same size (e.g., same diameter), and the iris diaphragms 30 are identical and interchangeable; however, this is not required, and in some embodiments the through-holes 36 may be of different sizes and similarly the iris diaphragms 30 may be of different sizes (e.g., they may have different maximum opening sizes). For example, if it is expected that the holes of the gas distribution plate 22 generally should increase with increasing distance away from the center of the gas distribution plate 22, then the sizes (e.g., diameters) of the through-holes 36 may be larger near the periphery of the gas distribution plate 22 compared with near the center, and similarly the iris diaphragms 30 may have larger maximum sizes of their respective openings 32 near the periphery of the gas distribution plate 22 compared with near the center. Conversely, if it is expected that the holes of the gas distribution plate 22 generally should decrease with increasing distance away from the center of the gas distribution plate 22, then the sizes (e.g., diameters) of the through-holes 36 may be smaller near the periphery of the gas distribution plate 22 compared with near the center, and similarly the iris diaphragms 30 may have smaller maximum sizes of their respective openings 32 near the periphery of the gas distribution plate 22 compared with near the center.

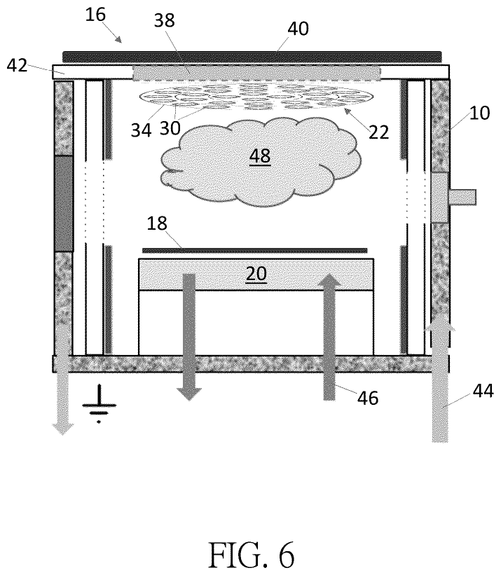

With reference now to FIG. 5, some suitable approaches for manufacturing or assembling the gas distribution plate 22 are described. As shown in FIG. 5, the mounting plate 34 includes the through-holes 36 over or within which the respective iris diaphragms 30 are disposed. The mounting plate 34 may be a stock plate of stainless steel, an aluminum alloy, or any other suitably rigid material that is not unduly reactive with the gas or gases that are flowed in the semiconductor processing apparatus. The through-holes 36 can be formed in the stock plate by drilling, laser cutting, punching, or any other suitable process. The through-holes 36 of the mounting plate 34 in some embodiments may be sockets into which the respective iris diaphragms 30 are mounted. For example, each iris diaphragm 30 could have a peripheral threading, and each through-hole 36 then has mating inner-diameter threading, so that each iris diaphragm 30 can be threaded or screwed into the corresponding through-hole 36 of the mounting plate 34. Alternatively the iris diaphragms 30 may be mounted over corresponding through-holes 36 of the mounting plate 34. That is, each iris diaphragm 30 is positioned with its opening 32 aligned with the corresponding through-hole 36 of the mounting plate 34. In this approach, fasteners (or openings that receive fasteners, such as blind threaded openings) enable securing the iris diaphragm 30 to the mounting plate 34 aligned with (e.g., over) the corresponding through-hole 36 of the mounting plate 34. In this approach, the through-hole 36 should have a diameter that is larger than or equal to the maximum size to which the iris diaphragm 30 can be opened (so that the edge of the through-hole does not block any portion of the opening of the iris diaphragm when it is opened to its maximum diameter), while the through-hole 36 should be smaller than the area of the iris diaphragm 30 (so that fasteners can engage the periphery of the iris diaphragm 30).

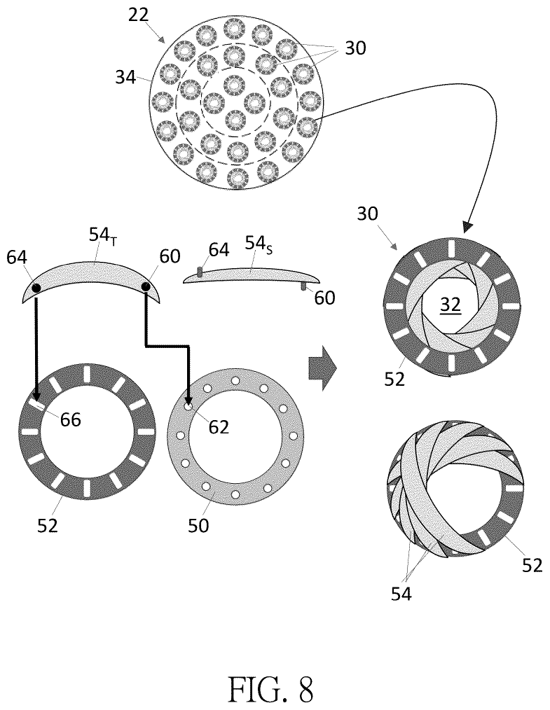

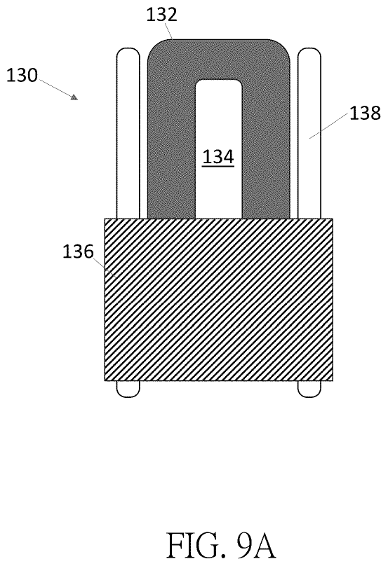

In some embodiments, the iris diaphragms 30 may be detachably secured to the mounting plate 34 (e.g., by being threaded into threaded through-holes 36, or secured to the mounting plate 34 by removable screws or bolts or the like). This is advantageous because the iris diaphragms 30 have intricate moving parts (see description herein referring to FIGS. 7 and 8), so that if an iris diaphragm becomes nonfunctional or has degraded function over time due to buildup of contamination in and/or on the parts of the iris diaphragm it can be removed and replaced. However, it is alternatively contemplated for the iris diaphragms 30 to be permanently secured to the mounting plate 34, e.g. by welding or the like for example.

The disclosed embodiments of a gas distribution plate 22 for a semiconductor processing apparatus can be employed in any type of semiconductor processing apparatus that employs a process chamber 10 that receives a gas flow that is to be distributed over a semiconductor wafer 18 undergoing processing. For example, the semiconductor processing apparatus may be a dry etching tool, a plasma etching tool, a CVD tool, a PECVD tool, or a combination thereof (e.g., a multipurpose semiconductor processing apparatus that can be configured to perform different types of deposition and/or etching).

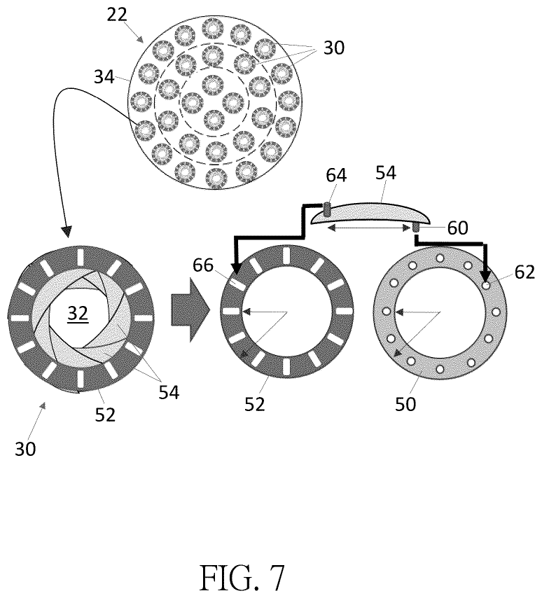

By way of a further nonlimiting illustrative example, FIG. 6 diagrammatically illustrates a side sectional view of a portion of another semiconductor processing apparatus, which includes the gas distribution plate 22 with holes comprising openings of iris diaphragms 30. In the nonlimiting illustrative example of FIG. 6, the lid 16 includes a lid heater 40 forming an upper boundary of the plenum 38, and a lid liner 42 which, inter alia, defines a sidewall of the plenum 38. The gas distribution plate 22 (again shown moved away from the lid 16 for illustrative purposes) forms the lower boundary of the plenum 38. The process chamber 10 optionally includes a hollow wall through which a coolant gas 44 may flow, and similarly the wafer mount 20 may optionally include flow passages through which a wafer mount coolant 46 flows. To provide for delivery of RF power to generate a plasma 48 inside the process chamber 10, the lower portion is electrically grounded to serve as RF cathode, while the lid heater 40 serves as the RF anode.

With reference now to FIGS. 7 and 8, some nonlimiting illustrative embodiments of construction of the iris diaphragms 30 are described. For context, FIG. 7 shows a top view of the gas distribution plate 22 including the iris diaphragms 30, analogous to FIG. 2. FIG. 7 further illustrates an enlarged view of one representative iris diaphragm 30 on the lower left with its opening 32. As shown on the lower right of FIG. 7, the iris diaphragm 30 is constructed of a hinge ring 50 and a rotating ring 52 which engage opposite ends of a plurality of iris leaves 54. The lower right of FIG. 7 shows one representative iris leaf 54 in isolation, with an outer engagement pin 60 at one end of the iris leaf 54 that engages an opening 62 of the hinge ring 50, and an inner engagement pin 64 on an opposite end of the iris leaf 54 which engages a slot 66 of the rotating ring 52. As seen in the enlarged view of an assembled iris diaphragm 30 in the lower left of FIG. 7, a plurality of such iris leaves 54 arranged at intervals around the circumference of the coaxially arranged hinge and rotating rings 50 and 52 respectively provide for the opening 32 which is approximately circular. The size of the opening 32 can be adjusted by rotation of the rotating ring 52 respective to the hinge ring 50, so that the pin 64 moves along the slot 66 of the rotating ring 52. FIG. 7 shows a simplified diagrammatic example of the rotating ring 52; in some practical implementations the slots 66 of the rotating ring may be arcuate, or otherwise-shaped, to guide the pins 64 of the iris leaves 54 along designed trajectories to improve circularity of the opening 32 over its range from minimum size of the opening 32 to maximum size of the opening 32.

FIG. 8 for context again shows a top view of the gas distribution plate 22 including the iris diaphragms 30, analogous to FIG. 2. FIG. 8 further illustrates top views of the hinge ring 50 and rotating ring 52, a top view 50T of a representative iris leaf 50, and a side view 50s of a representative iris leaf 50, each showing the outer engagement pin 60 at one end of the iris leaf 54 that engages an opening 62 of the hinge ring 50, and the inner engagement pin 64 on the opposite end of the iris leaf 54 which engages the slot 66 of the rotating ring 52. The lower rightmost drawing of FIG. 7 shows a view of an iris diaphragm partially disassembled to include only the rotating ring 52 and five iris leaves 54, while an enlarged view of a fully assembled iris diaphragm 30 is also shown in FIG. 8, illustrating formation of the opening 32 of the representative iris diaphragm 30.

It will be appreciated that the illustrative embodiment of the iris diaphragm 30 described with reference to FIGS. 7 and 8 is a nonlimiting example. Other suitable constructions of the iris diaphragms are also contemplated.

Moreover, it is contemplated to replace the illustrative iris diaphragms 30 with other suitable adjustable-opening devices, such as slotted apertures.

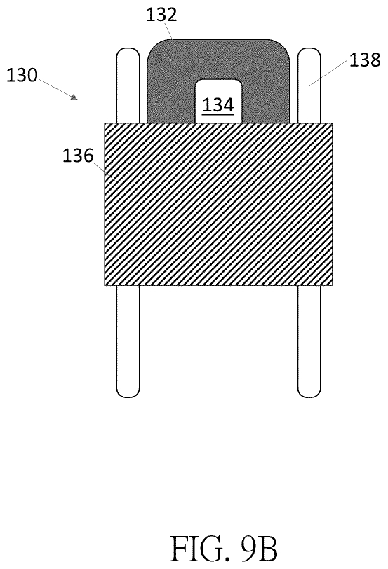

With reference to FIGS. 9A and 9B, top views are shown of a nonlimiting illustrative embodiment of a slotted aperture 130 that may suitably be used in place of the illustrative iris diaphragms 30 in some embodiments to provide adjustable openings for a gas distribution plate. FIGS. 9A and 9B show the slotted aperture 130 with two nonlimiting illustrative opening settings. The illustrative slotted aperture 130 include a base plate 132 having an aperture 134, and a sliding plate 136 that slides along grooves 138 on opposite sides of the aperture 134 to control how much of the aperture 134 is covered by the sliding plate 136. FIG. 9A shows the slot aperture 130 with a large opening (i.e., only a small portion, or no portion, of the aperture 134 covered by the sliding plate 136. FIG. 9B shows the slot aperture 130 with a small opening (i.e., most of the aperture 134 covered by the sliding plate 136. This provides an adjustable opening analogous to the adjustable opening 132 of the iris diaphragm 30. In the embodiment of FIGS. 9A and 9B, it is contemplated for the base plate 132 to comprise the mounting plate 34 of the gas distribution plate, with the apertures 134 and grooves 138 drilled or otherwise cut or formed into the mounting plate.

In some embodiments of the gas distribution plate 22, the iris diaphragms 30 are manually operable.

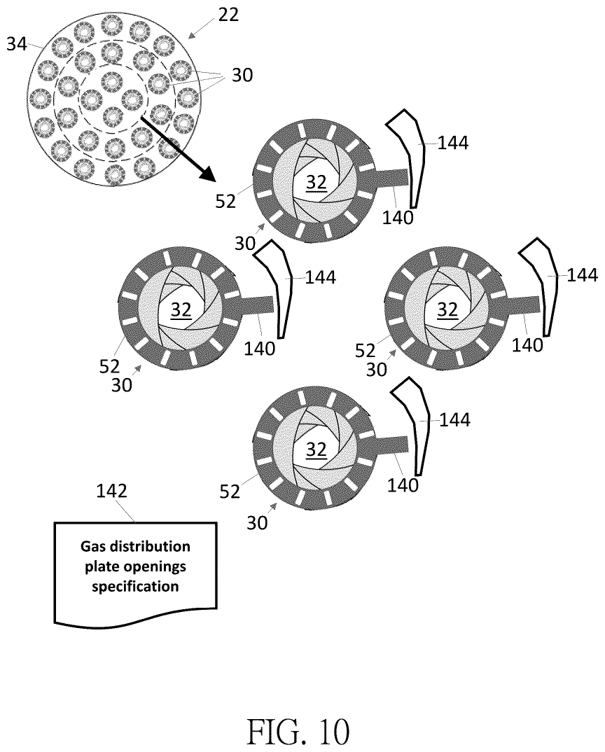

FIG. 10 diagrammatically illustrates a top view of the gas distribution plate 22 (e.g., analogous to FIG. 2), and further shows an enlarged top view of an illustrative four central iris diaphragms 30 configured for independent manual adjustment of the respective iris diaphragms according to one nonlimiting illustrative embodiment. In the example of FIG. 10, the rotating ring 52 of each iris diaphragm 30 includes a knob or pin or the like 140 via which a user can manually rotate the rotating ring 52 using his or her finger. In this embodiment, the user retrieves or receives a (diagrammatically indicated) specification 142 of gas distribution plate openings, which specifies the opening 32 for each iris diaphragm 30 of the gas distribution plate 22. Optionally, the periphery of each iris diaphragm 30 includes tic marks, numbers, a graphical scale, or another engraved or otherwise-marked scale 144 via which the user can recognize the size of the opening 32 based on the rotational position of the knob or pin 140. In such manual embodiments, the user would go through and set the openings 32 prior to a semiconductor wafer processing run in accordance with the specification 142 of gas distribution plate openings for that run. Since adjusting the openings 32 of the respective iris diaphragms 30 of the gas distribution plate 22 is manually intensive, in a suitable approach this is done before a series of semiconductor wafer processing runs of the same type (e.g., to produce multiple batches of processed wafers.

If the iris diaphragms 30 are replaced by slotted apertures 130 as previously described with reference to FIGS. 9A and 9B, then the knob or pin 140 may suitably connect with the sliding plate 136 to allow manual adjustment of its position.

In some embodiments of the gas distribution plate 22, the iris diaphragms 30 are automated by individual motors driving the respective iris diaphragms.

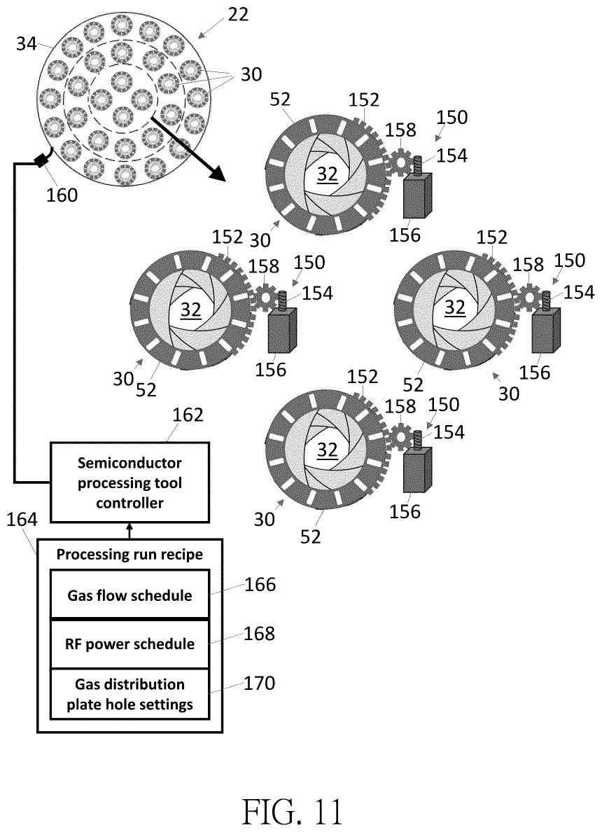

FIG. 11 diagrammatically illustrates a top view of the gas distribution plate 22 (e.g., analogous to FIG. 2), and further shows an enlarged top view of an illustrative four central iris diaphragms 30 configured for independent automated adjustment of the respective iris diaphragms 30 according to one nonlimiting illustrative embodiment. The iris diaphragms 30 of the gas distribution plate 22 in the embodiment of FIG. 11 have motorized actuators 150 via which the iris diaphragms 30 are individually operable to adjust the openings 32 of the respective iris diaphragms 30 of the gas distribution plate 22. In the nonlimiting illustrative example, each motorized actuator 150 includes gear teeth 152 disposed on an outer perimeter of a rotating ring 52 of the iris diaphragm 30, a worm drive 154 operatively coupled with the gear teeth 152, and a (micro) motor 156 connected to drive the worm drive 154. In the illustrative example, the worm drive 154 is operatively coupled with the gear teeth 152 by way of a gear ring 158; however, a direct coupling or other type of coupling is also contemplated.

Electrical conductors (not shown) for powering the motors 156 of the motorized actuators 150 are suitably disposed along the surface of the mounting plate 34 and formed into a wire bundle or cable that connects to an electrical feedthrough 160 of the process chamber 10 or its lid 16. Each motorized actuator 150 may further include a rotary position sensor (such as an optical rotary encoder) or other sensor (not shown) that measures the size of the opening 32 or a parameter correlated therewith (such as a rotational angle of the worm drive 154 measured by a rotary positions sensor, where the measured rotational angle may be greater than 360°, that is, multiple revolutions of the worm drive 154 may be monitored).

If the iris diaphragms 30 are replaced by slotted apertures 130 as previously described with reference to FIGS. 9A and 9B, then the motorized actuators 150 may suitably engage with the sliding plate 136 to allow automated adjustment of its position. For example, the gear teeth 152 can be disposed on the sliding plate 136.

Automated adjustment of the respective iris diaphragms 30 (or, alternatively, slotted apertures 130) by motorized actuators 150 increases flexibility of the use of the gas distribution plate 22. For example, in the example of FIG. 11, a semiconductor processing tool controller 162 (for example, a computer or other electronic device having a microprocessor, microcontroller, or the like and associated electronic memory and/or other data storage) is operatively connected with the semiconductor processing apparatus (e.g., as diagrammatically shown in FIG. 1), and is programmed to control the semiconductor processing apparatus to perform a processing run according to a processing run recipe 164. The run recipe 164 includes a gas flow schedule 166 specifying flow parameters for the gas used in the semiconductor wafer processing run (e.g., constituent gas or gases, flow rate in sccm or other suitable units, et cetera, where these parameters may vary over time over the course of the run and/or different constituent gases may be switched on and off over the course of the run) and an optional RF power schedule 168 specifying RF parameters for plasma generation (e.g., specifying RF parameters such as RF power, RF frequency, and/or so forth where again these parameters may vary over time over the course of the run).

As disclosed herein, in the embodiment of FIG. 11 the run recipe 164 further includes gas distribution plate hole settings 170 for the run, which specifies the opening 32 for each iris diaphragm 30 (or, alternatively, for each slotted aperture 130). Thus, when the run recipe 164 is loaded into the semiconductor processing tool controller 162, it advantageously automatically sets the opening 32 for each iris diaphragm 30 (or, alternatively, for each slotted aperture 130) prior to the run.

Advantageously, it is also possible for the gas distribution plate hole settings 170 for the run to be a schedule, in which the specified openings 32 for the iris diaphragms 30 (or, alternatively, for the slotted apertures 130) may vary over time over the course of the run. For example, if the run includes switching from a first etchant to a second etchant, where the optimal openings of the gas distribution plate 22 are different for the first gas versus the second gas, then the gas distribution plate hole settings schedule 170 may adjust the opening 32 at the transition from the first etchant to the second etchant. This advantageously enables the gas distribution plate 22 in the automated embodiment of FIG. 11 to control of the gas flow distribution as a function of time over the course of a run, enabling tailoring of the gas flow distribution in a manner that is not achievable by a gas distribution plate with fixed-size holes.

In the following, some further embodiments are described.

In a nonlimiting illustrative embodiment, a semiconductor processing apparatus includes: a process chamber; a gas distribution plate disposed in the process chamber, the gas distribution plate including iris diaphragms and having holes comprising openings of the iris diaphragms; a gas inlet or gas mixer arranged to flow gas into the process chamber through the iris diaphragms of the gas distribution plate; and a wafer holder arranged in the process chamber to receive the gas after the gas flows through the iris diaphragms of the gas distribution plate.

In a nonlimiting illustrative embodiment, a semiconductor processing method includes: flowing a gas into a process chamber containing an associated semiconductor wafer; distributing the gas onto a surface of the associated semiconductor wafer by flowing the gas through holes of a gas distribution plate; and, before the flowing and the distributing, configuring the distribution of the gas by adjusting sizes of the holes of the gas distribution plate.

In a nonlimiting illustrative embodiment, a gas distribution plate for a semiconductor processing apparatus includes a mounting plate having through-holes, and iris diaphragms or slotted apertures mounted over or in respective through-holes of the mounting plate.

In some nonlimiting illustrative embodiments, a gas distribution plate for a semiconductor processing apparatus includes a mounting plate having through-holes, and iris diaphragms or slotted apertures mounted over or in respective through-holes of the mounting plate. Each iris diaphragm or slotted aperture includes a motorized actuator operable to adjust the opening of the iris diaphragm or slotted aperture. In some embodiments, the gas distribution plate includes iris diaphragms, each including a hinge ring, a rotating ring, and iris leaves each having a first end coupled with the hinge ring and a second end opposite the first end slidably coupled with the rotating ring. If motorized, the motorized actuator may include a motor and a worm drive driven by the motor, with the worm drive operatively coupled with gear teeth disposed on the rotating ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing apparatus comprising:
a process chamber;
a gas distribution plate disposed in the process chamber, the gas distribution plate including iris diaphragms and having holes comprising openings of the iris diaphragms;
a gas inlet or gas mixer arranged to flow gas into the process chamber through the iris diaphragms of the gas distribution plate; and
a wafer holder arranged in the process chamber to receive the gas after the gas flows through the iris diaphragms of the gas distribution plate.

2. The semiconductor processing apparatus of claim 1, wherein the gas distribution plate further includes:
a mounting plate having through-holes;
wherein the iris diaphragms are mounted over or in respective through-holes of the mounting plate.

3. The semiconductor processing apparatus of claim 1, wherein the iris diaphragms of the gas distribution plate have knobs via which the iris diaphragms are individually operable to adjust the openings of the respective iris diaphragms of the gas distribution plate.

4. The semiconductor processing apparatus of claim 1, wherein the iris diaphragms of the gas distribution plate have motorized actuators via which the iris diaphragms are individually operable to adjust the openings of the respective iris diaphragms of the gas distribution plate.

5. The semiconductor processing apparatus of claim 4, further comprising:
a controller configured to cause the semiconductor process chamber to execute a processing run recipe including:
automatically controlling the motorized actuators of the respective iris diaphragms of the gas distribution plate to operate the respective iris diaphragms to adjust the sizes of the openings of the respective iris diaphragms of the gas distribution plate according to gas distribution plate hole settings of the processing run recipe; and
controlling the flow of the gas from the gas inlet or gas mixer into the process chamber through the iris diaphragms according to a gas flow schedule of the processing run recipe.

6. The semiconductor processing apparatus of claim 4, wherein the motorized actuator of each iris diaphragm of the gas distribution plate includes:
gear teeth disposed on an outer perimeter of a rotating ring of the iris diaphragm;
a worm drive operatively coupled with the gear teeth; and
a motor connected to drive the worm drive.

7. The semiconductor processing apparatus of claim 1, wherein the iris diaphragms of the gas distribution plate each includes:
a hinge ring;
a rotating ring; and
iris leaves each having a first end coupled with the hinge ring and a second end opposite the first end slidably coupled with the rotating ring.

8. The semiconductor processing apparatus of claim 1, further comprising:
high voltage radio frequency (RF) electrodes arranged to generate an RF field in the process chamber operative to ionize at least a portion of the gas in the process chamber to form a plasma in the process chamber.

9. The semiconductor processing apparatus of claim 1, wherein the semiconductor processing apparatus is a dry etching tool, a plasma etching tool, a chemical vapor deposition (CVD) tool, a plasma-enhanced chemical vapor deposition (PECVD) tool, or a combination thereof.

10. A semiconductor processing method comprising:
flowing a gas into a process chamber containing an associated semiconductor wafer;
distributing the gas onto a surface of the associated semiconductor wafer by flowing the gas through holes of a gas distribution plate; and
before the flowing and the distributing, configuring the distribution of the gas by adjusting sizes of the holes of the gas distribution plate.

11. The semiconductor processing method of claim 10, wherein:
the gas distribution plate includes iris diaphragms or slotted apertures, and the holes of the gas distribution plate comprise openings of the iris diaphragms or slotted apertures; and
the sizes of the holes of the gas distribution plate are adjusted by operating the iris diaphragms or slotted apertures to adjust the openings of the iris diaphragms or slotted apertures.

12. The semiconductor processing method of claim 11, wherein the operating of the iris diaphragms or slotted apertures includes:
operating the iris diaphragms or slotted apertures using knobs or pins of the respective iris diaphragms or slotted apertures to adjust the openings of the respective iris diaphragms or slotted apertures.

13. The semiconductor processing method of claim 11, wherein the operating of the iris diaphragms or slotted apertures includes:
operating motorized actuators of the respective iris diaphragms or slotted apertures to adjust the openings of the respective iris diaphragms or slotted apertures.

14. The semiconductor processing method of claim 13, further comprising:
electronically controlling the semiconductor process chamber to automatically execute a processing run recipe including:
automatically controlling the motorized actuators of the respective iris diaphragms or slotted apertures of the gas distribution plate to operate the respective iris diaphragms or slotted apertures to adjust the sizes of the openings of the respective iris diaphragms or slotted apertures of the gas distribution plate according to gas distribution plate hole settings of the processing run recipe; and
automatically controlling the flowing of the gas into the process chamber according to a gas flow schedule of the processing run recipe.

15. The semiconductor processing method of claim 10, further comprising:
energizing electrodes arranged to generate a high voltage radio frequency (RF) field in the process chamber that ionizes at least a portion of the gas in the process chamber to form a plasma in the process chamber.

16. The semiconductor processing method of claim 10, wherein the semiconductor processing method is a chemical vapor deposition (CVD) method and the gas distributed onto the surface of the associated semiconductor wafer causes deposition of a material on at least a portion of the surface of the associated semiconductor wafer.

17. The semiconductor processing method of claim 10, wherein the semiconductor processing method is a dry etching method and the gas distributed onto the surface of the associated semiconductor wafer causes etching of at least a portion of the surface of the associated semiconductor wafer.

18. A gas distribution plate for a semiconductor processing apparatus, the gas distribution plate comprising:
a mounting plate having through-holes; and
iris diaphragms or slotted apertures mounted over or in respective through-holes of the mounting plate.

19. The gas distribution plate of claim 18, wherein each iris diaphragm or slotted aperture includes a motorized actuator operable to adjust an opening of the iris diaphragm or slotted aperture.

20. The semiconductor process chamber of claim 19, wherein each iris diaphragm or slotted aperture is an iris diaphragm that further includes:
a hinge ring;
a rotating ring; and
iris leaves each having a first end coupled with the hinge ring and a second end opposite the first end slidably coupled with the rotating ring;
wherein the motorized actuator of the iris diaphragm comprises a motor and a worm drive driven by the motor; and
wherein the worm drive is operatively coupled with gear teeth disposed on the rotating ring.
